(19) United States
(12) Patent Application Publication
(10) Pub. No.: US 2011/0195569 A1
(43) Pub. Date: Aug. 11, 2011

(54) Semiconductor Device and Method for Forming the Same

(76) Inventors: Kwangjin Moon, Suwon-si (KR); Gilheyun Choi, Seoul (KR); Jongmyeong Lee, Seongnam-si (KR); Zungsun Choi, Seoul (KR); Hye Kyung Jung, Seoul (KR)

(21) Appl. No.: 13/024,899

(22) Filed: Feb. 10, 2011

(30) Foreign Application Priority Data
Feb. 10, 2010 (KR) 10-2010-0012491

(51) Int. Cl. H01L 21/768

(52) U.S. Cl. 438/643; 257/E21.584

(57) ABSTRACT

Methods of forming field effect transistors include forming a metal alloy gate electrode (e.g., aluminum alloy) containing about 0.5 to about 1.0 atomic percent silicon, on a substrate, and electroless plating an electrically conductive gate protection layer directly on at least a portion of an upper surface of the metal alloy gate electrode. A gate dielectric layer may be formed on the substrate. This gate dielectric layer may have a dielectric constant greater than a dielectric constant of silicon dioxide. The forming of the metal alloy gate electrode may include forming a metal alloy gate electrode directly on an upper surface of the gate dielectric layer.

### REFERENCE TO PRIORITY APPLICATION

This application claims priority to Korean Patent Application No. 10-2010-0012491, filed Feb. 10, 2010, the contents of which are hereby incorporated herein by reference.

### FIELD

The present invention relates to semiconductors and, more specifically to semiconductor devices including gate contacts.

### BACKGROUND

Semiconductor devices can be classified into memory devices and logic devices. Memory devices are a device that stores data. Such memory device can be classified into volatile memory devices and non-volatile memory devices depending on the way of storing data. Volatile memory devices lose stored data when power goes off. DRAM devices and SRAM devices are representative volatile memory devices. Non-volatile memory devices can retain information even when power goes off. Flash memory devices, phase change memory devices or magnetic memory devices are representative non-volatile memory devices. Logic devices can process data or execute pre-determined instructions

Due to their features of miniaturization, multi-function and/or high speed, semiconductor devices functions as an important element in the electronic industry. Accordingly, as the electronic industry advances, the needs for high-integration, multi-functionality, high-speed, reproducibility and/or reliability are more and more increasing. Generally, however, the foregoing needs have trade-off relationships with each other. Therefore, it is becoming more and more difficult to meet the foregoing various needs simultaneously. For example, as a line width and/or a space of semiconductor patterns, which is included in a semiconductor device, decreases, it becomes more challenging to increase the operating speed of a semiconductor device. In addition, as a line width and/or a space of semiconductor patterns decreases, it becomes more difficult to achieve reliability and/or reproducibility of a semiconductor device. Currently, the electronic industry is advancing very rapidly. Therefore, various studies are being under way to meet the various needs for semiconductor devices.

### SUMMARY

Methods of forming field effect transistors include forming a metal alloy gate electrode (e.g., aluminum alloy) containing about 0.5 to about 1.0 atomic percent silicon, on a substrate, and electroless plating an electrically conductive gate protection layer directly on at least a portion of an upper surface of the metal alloy gate electrode. A gate dielectric layer may also be formed on the substrate. This gate dielectric layer may have a dielectric constant greater than a dielectric constant of silicon dioxide. The forming of the metal alloy gate electrode may include forming a metal alloy gate electrode directly on an upper surface of the gate dielectric layer. The electrically conductive gate protection layer may include a metal alloy selected from a group consisting of a cobalt alloy and a nickel alloy. The metal alloy may also include at least one of tungsten and phosphorous.

Additional embodiments of the invention include depositing a barrier layer on the electrically conductive gate protection layer. The barrier layer may include at least one of a titanium nitride layer, a tungsten nitride layer and a tungsten carbonitride layer. According to additional embodiments of the invention, the forming of a metal alloy gate electrode is preceded by forming a dummy dielectric pattern on the substrate and forming a dummy gate pattern on an upper surface of the dummy dielectric pattern. Gate spacers may also be formed on sidewalls of the dummy gate pattern. The dummy gate pattern and the dummy dielectric pattern may be removed in sequence to expose inner sidewalls of the gate spacers. This removing may be followed by forming a gate dielectric layer on a portion of the substrate extending between the inner sidewalls of the gate spacers. The forming of the gate dielectric layer may also be followed by depositing a provisional liner directly on the inner sidewalls of the gate spacers and directly on an upper surface of the gate dielectric layer. The provisional liner may be formed as an oxide, a nitride or an oxynitride and the gate dielectric layer may include a metal oxide containing hafnium. According to still further embodiments of the invention, the electroless plating may include using dimethyl amino borane and/or morpholine borane as a reducing agent and using nickel sulfate and/or cobalt sulfate as a precursor.

### BRIEF DESCRIPTION OF THE DRAWINGS

The accompanying drawings are included to provide a further understanding of the present inventive concept, and are incorporated in and constitute a part of this specification. The drawings illustrate exemplary embodiments of the present inventive concept and, together with the description, serve to explain principles of the present inventive concept. In the figures:

FIGS. 1 through 9 are cross-sectional views of a semiconductor device and a manufacturing method thereof according to one embodiment of the present inventive concept.

FIGS. 10 through 16 are cross-sectional views of a semiconductor device and a manufacturing method thereof according to another embodiment of the present inventive concept.

### DETAILED DESCRIPTION OF THE EMBODIMENTS

The advantages and features of the present inventive concept and ways of achieving them will become apparent referring to embodiments below in combination with the accompanying drawings. The embodiments of the present inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The present inventive concept is only defined by the scope as delineated in the claims. Like numerals in this specification refer to like elements throughout.

In this specification, it will be understood that when a layer such as a conductive layer, semiconductor layer or dielectric layer is referred to as being “on” another element, it can be directly on the other element or intervening elements may also be present. In addition, It will be understood that, although the terms first, second, third etc. may be used herein to describe material layers and/or process steps, these material layers and/or process steps should not be limited by these terms. These terms are only used to distinguish one material layers and/or process steps from another material layers and/or process steps.

It will be understood that the termed used in this specification is to explain the present inventive concept, and not to limit it. Unless mentioned otherwise, a singular form also includes a plural form. It will be further understood that the terms “comprises” and/or “comprising,” when used in this specification, specify the presence of stated elements, steps, operations and/or device components thereof, but do not preclude the presence or addition of one or more other, elements, steps, operations and/or device components thereof.

Embodiments of the present inventive concept will be explained in detail with reference to the ideal illustrations, such as cross-sectional views and/or plain views. In the drawings, the thicknesses of layers and regions are exaggerated for the effective explanation of the technical concept. Accordingly, the illustration can be modified by manufacturing technologies and/or tolerance. Embodiments of the present inventive concept are not limited to the specific shape illustrated herein, but include various shapes formed by different manufacturing processes. For example, an etched area illustrated as having a right angle may have a rounded shape or a shape having a predetermined curvature. Therefore, it will be understood that the illustrated regions in the drawings outline attributes and illustrate specific exemplary shapes, and do not limit the scope of the present inventive concept.

Hereinafter, semiconductor devices and methods of manufacturing thereof embodiments of the present inventive concept will be explained in detail with reference to the accompanying drawings.

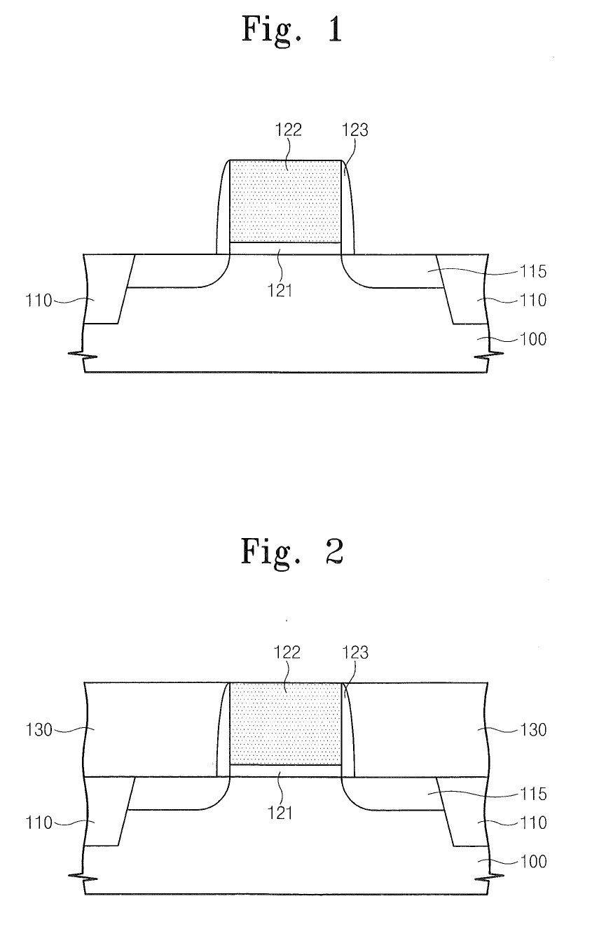

FIGS. 1 through 9 are cross-sectional views illustrating a semiconductor device and a manufacturing method thereof according to one embodiment of the present inventive concept.

Referring to FIG. 1, a device isolation pattern 110 may be formed on a substrate 100 to define an active region. The substrate 100 may comprise a pre-determined semiconductor based structure having a silicon surface. Such pre-determined semiconductor based structure may be silicon, silicon-on-insulator (SOI), or a silicon epitaxial layer supported by a semiconductor structure. The device isolation pattern 110 may be a trench-type device isolation pattern. For example, the device isolation pattern 110 may be formed by forming a trench in the substrate 100 and filling the trench with a dielectric material.

A dummy pattern may be provided on the substrate 100. The dummy pattern may be a structure for the damascene process, which will be explained below. The dummy pattern may comprise a dummy dielectric pattern 121 and a dummy gate pattern 122. A channel region may be defined in an active region under the dummy pattern. The dummy dielectric pattern 121 and the dummy gate pattern 122 may be formed by forming a dielectric layer and a polysilicon layer on the substrate 100 and patterning them. A source/drain region 115 may be formed on the substrate of both sides of the dummy pattern. The source/drain region 115 may comprise a dopant that is an opposite type to a dopant in the channel region. A gate spacer 123 may be formed on a sidewall of the dummy pattern. The source/drain region 115 may be formed as a LDD structure using the gate spacer 123.

Referring to FIG. 2, a first interlayer dielectric 130 may be formed on the substrate 100. The first interlayer dielectric 130 may be planarized until the dummy gate pattern 122 is exposed. The upper surface of the planarized first interlayer dielectric 130 may be co-planar with the upper surface of the dummy gate pattern 122. The dummy gate pattern 122 may comprise a material that has etching selectivity with respect to the first interlayer dielectric 130.

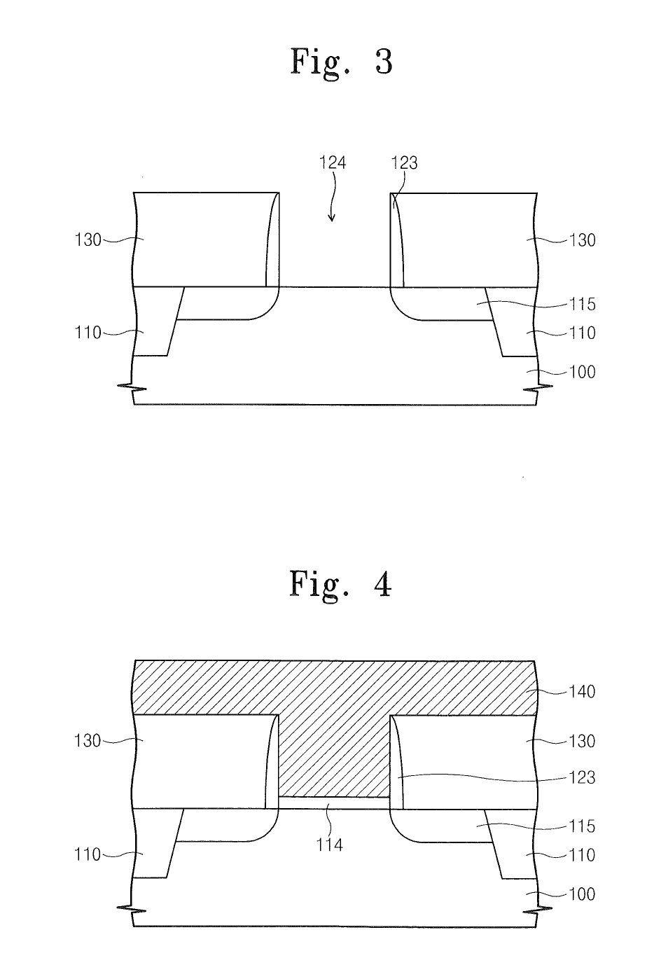

Referring to FIG. 3, a recess region 124 may be formed by removing the dummy gate pattern 122 and the dummy dielectric pattern 121. The dummy gate pattern 122 and the dummy dielectric pattern 121 may be removed by a selective etching process. The recess region 124 may expose the substrate 100. Impurities to adjust a threshold voltage may be doped in a channel region under the recess region 124. Doping the impurity may be performed using the first interlayer dielectric 130 as a mask. When performing doping the impurity, a portion of the dummy dielectric pattern 121 may remain and be used as a buffer layer for an ion implantation.

Referring to FIG. 4, a gate dielectric layer 114 may be formed on a lower area of the recess region 124. The gate dielectric layer 114 may comprise a high-k film having a high dielectric constant. The gate dielectric layer 114 may comprise at least one selected from the group consisting of a metal oxide, for example, hafnium oxide, and metal-semiconductor-oxide compound film, for example, hafnium-silicon-oxygen-nitrogen compound. The gate dielectric layer 114 may be formed by Chemical Vapor Deposition (CVD) or Atomic Layer Deposition (ALD). A first conductive layer 140 may be formed on the gate dielectric layer 114, filling the recess region 124. The first conductive layer 140 may comprise aluminum (Al). The first conductive layer 140 may further comprise silicon (Si). The silicon may reduce void formations due to electro-migration or stress-migration phenomena of a metal gate electrode, which will be explained below, thereby improving thermal stability. But, in the case that the atomic percent of silicon exceeds 1%, the resistivity of the metal gate electrode may increase. Therefore, the silicon contents of 0.5˜1% (atomic percent) is preferred. The first conductive layer 140 may be formed by Physical Vapor Deposition (PVD).

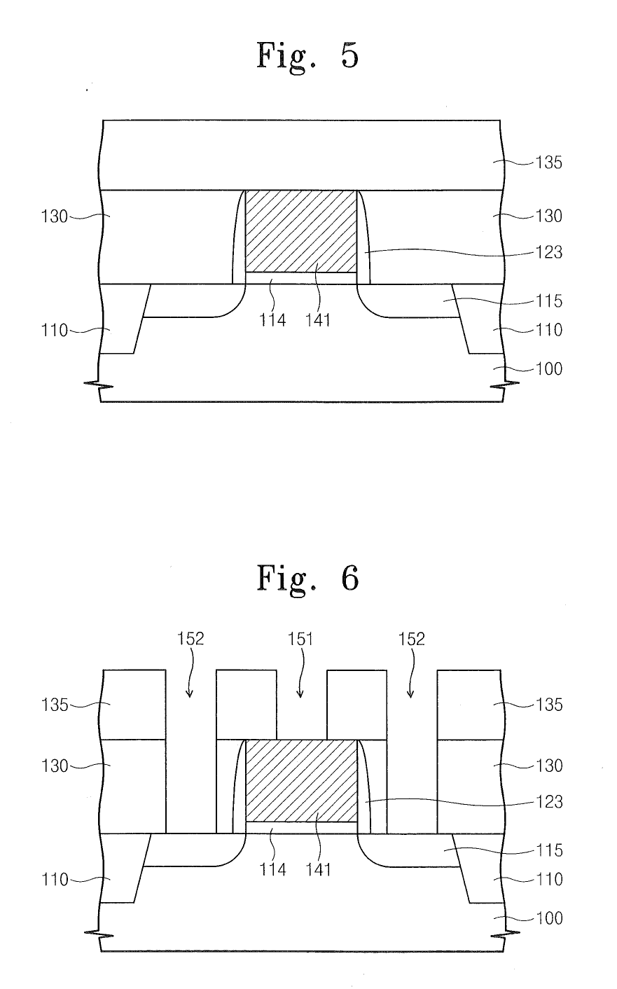

Referring FIG. 5, the first conductive layer 140 may be planarized until the first interlayer dielectric 130 is exposed. The planarization process may be an etch-back or Chemical Mechanical Polishing (CMP). By the planarization process, a metal gate electrode 141 may be formed. The metal gate electrode 141 may be formed by methods other than the damascene process as described above. For example, the metal gate electrode 141 may be formed, without dummy patterns, by forming a high-k film and a conductive layer on the substrate 100 and patterning them. A second interlayer dielectric 135 may be formed on the metal gate electrode 141 and the first interlayer dielectric 130. The second interlayer dielectric 135 may be an oxide, nitride, or oxynitride layer. The second interlayer dielectric 135 may be formed by CVD.

Referring to FIG. 6, a gate contact hole 151 and a drain/source contact hole 152 may be formed. The gate contact hole 151 may be formed, penetrating the second interlayer dielectric 135, to expose the upper surface of the metal gate electrode 141. The source/drain contact hole 152 may be formed, penetrating the first interlayer dielectric 130 and the second interlayer dielectric 135, to expose a source/drain region 115. The gate contact hole 151 may be formed simultaneously with the source/drain contact hole 152.

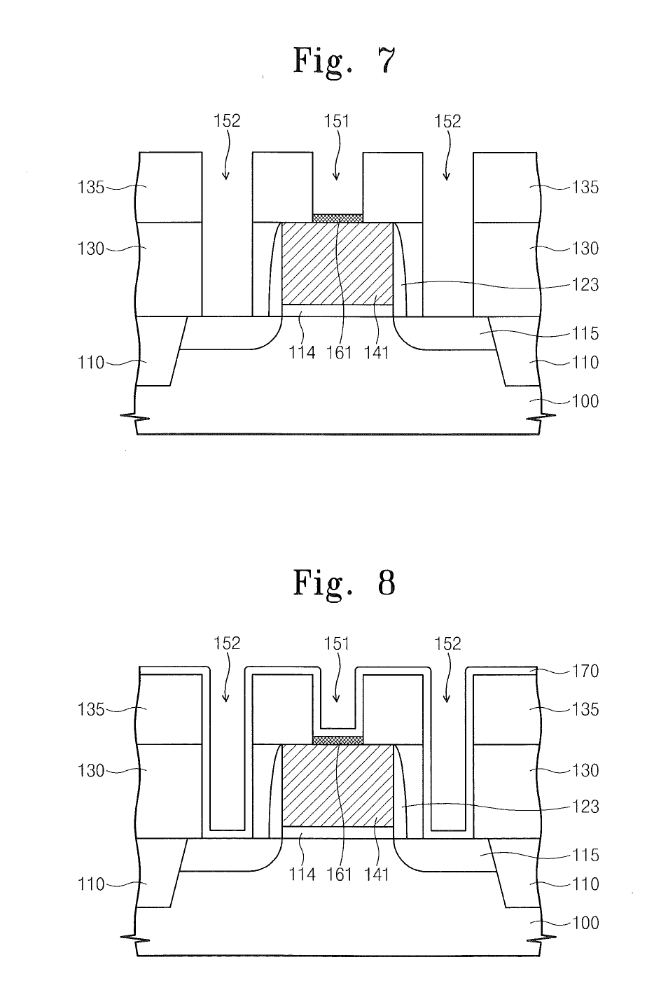

Referring to FIG. 7, a gate protection pattern 161 may be selectively formed on the upper surface of the metal gate electrode 141, which is exposed by the gate contact hole 151. The gate protection pattern 161 may be formed in a locally confined manner on the bottom portion of the gate contact hole 151 and may not be formed on the outside surface of the gate contact hole 151. In the case that the gate protection pattern 161 is formed ahead of the second interlayer dielectric 135, leakage current may increase since metallic contaminants which may occur during electroless plating process remain on the first interlayer dielectric 130. The electroless plating process will be explained below. In addition, during the selective CVD process to form the gate protection pattern 161, some materials may be formed on the first interlayer dielectric 130 outside of the metal gate electrode 141, thereby increasing leakage current. Forming the gate protection pattern 161 according to one embodiment of the present inventive concept may selectively form the gate protection pattern 161 on the metal gate electrode after forming the gate contact hole 151 to prevent occurrence of leakage current. The gate protection pattern 161 may comprise cobalt alloys or nickel alloys including tungsten (W) and/or phosphor (P). The gate protection pattern 161 may further comprise boron (B). The gate protection pattern 161 may be selectively formed on the exposed metal gate electrode 141 in the gate contact hole 151 and may not be formed on the exposed source/drain 115 in the source/drain contact hole 152. The gate protection pattern 161 may be selectively formed on the bottom portion of the gate contact hole 151, and may not be formed on an inner sidewall of the gate contact hole 151. As a result, reliability degradation of interconnections due to agglomeration, which may occur when forming the gate protection pattern 161 on the inner sidewall of the gate contact hole 151, may be prevented.

The gate protection pattern 161 may be formed by electroless plating. The electroless plating may use nickel sulfate (NiSO₄) and/or cobalt sulfate (CoSO₄) as a precursor. The electroless plating may use DMBA (Dimethyl Amino Borane) and/or MB (Morpholine Borane) as a reducing agent. The electroless plating may additionally use a catalyst. The electroless plating may be performed by oxidations of reducing agents and reduction of metal ions. In other words, oxidation of reducing agents supplies electrons, which combines with the metal ion and thereby forms a metal pattern. The electroless plating may be performed in a liquid of a temperature between 50 and 90° C. The electroless plating may be performed at the condition of pH 8˜12. The gate protection pattern 161 may be selectively formed on the metal gate electrode 141, which is exposed by the electroless plating. The gate protection pattern 161 may be formed by selective CVD. The selective CVD process may be performed using the difference of the thermodynamic stability between the exposed metal gate electrode 141 and other parts.

Referring to FIG. 8, a barrier layer 170 may be formed in the gate contact hole 151 and the source/drain contact hole 152. The barrier layer 170 may be a titanium nitride layer, tungsten nitride layer or tungsten carbonitride layer. The barrier layer 170 may be formed by CVD or ALD, which is performed at equal to or less than 450° C. The barrier layer 170 may be formed by using WF₆ or TiCl₄ as a source. Particularly, in the case that the metal gate electrode 141 comprises aluminum, a high resistivity material, such as TiAl₃ may be formed on the metal gate electrode 141 or corrosion of the metal gate electrode 141 may occur. When forming the barrier layer 170, the gate protection pattern 161 may prevent the formation of a high resistivity material and damages of the metal gate electrode 141.

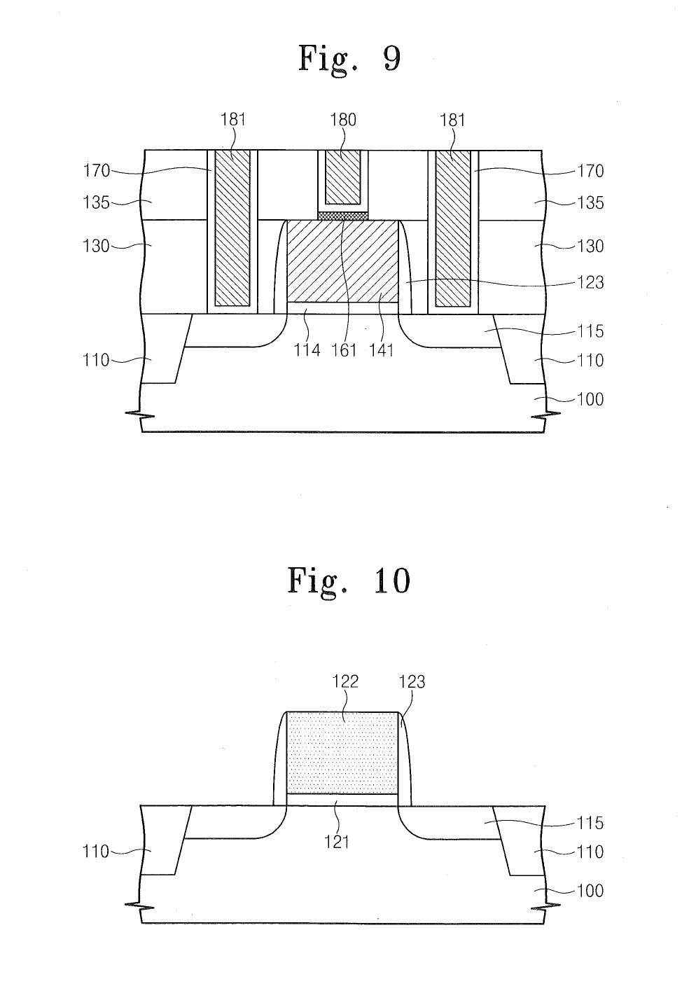

Referring to FIG. 9, a gate contact plug 180 may be formed in the gate contact hole 151 and a source/drain contact plug 181 may be formed in the source/drain contact hole 152. The gate contact plug 180 and the source/drain contact plug 181 may be formed, after forming a second conductive layer (not shown) on the barrier layer 170, by a planarization process. After the planarization process, the barrier layer 170 may be separated to be positioned on inner areas of the respective contact holes. The gate contact plug 180 and the source/drain contact plug 181 may comprise tungsten (W). The gate contact plug 180 and the source/drain contact plug 181 may be formed by CVD or PVD. The gate contact plug 180 and the source/drain contact plug 181 may be formed by using WF₆ as a source. When forming the barrier layer 170 or in the case that the barrier layer 170 is thin, the gate protection pattern 161 may prevent the metal gate electrode 141 from being damaged by the WF₆ during forming the contact plug.

Hereinafter, a semiconductor devices and a manufacturing method thereof according to another embodiments of the present inventive concept will be explained.

Except the shape of a gate protection pattern and the structure of a gate, this embodiment is, similar to the foregoing embodiment. Accordingly, for the brevity of explanation, overlapping technical features may be omitted.

FIGS. 10 through 16 are cross-sectional views of a semiconductor device and a manufacturing method thereof according to another embodiment of the present inventive concept.

Referring to FIG. 10, a device isolation pattern 110 may be formed on a substrate 100 to define an active region. The substrate 100 may comprise a pre-determined semiconductor based structure having a silicon surface. Such pre-determined semiconductor based structure may be silicon, silicon-on-insulator (SOI), or a silicon epitaxial layer supported by a semiconductor structure. The device isolation pattern 110 may be a trench-type device isolation pattern. For example, the device isolation pattern 110 may be formed by forming a trench in the substrate 100 and filling the trench with a dielectric material.

A dummy pattern may be provided on the substrate 100. The dummy pattern may be a structure for the damascene process, which will be explained below. The dummy pattern may comprise a dummy dielectric pattern 121 and a dummy gate pattern 122. A channel region may be defined on an active region under the dummy pattern. The dummy dielectric pattern 121 and the dummy gate pattern 122 may be formed by forming a dielectric layer and a polysilicon layer on the substrate 100 and patterning them. A source/drain region 115 may be formed on the substrate of both sides of the dummy pattern. The source/drain region 115 may comprise a dopant that is an opposite type to a dopant in the channel region. A gate spacer 123 may be formed on a sidewall of the dummy pattern. The source/drain region 115 may be formed as a LDD structure using the gate spacer 123.

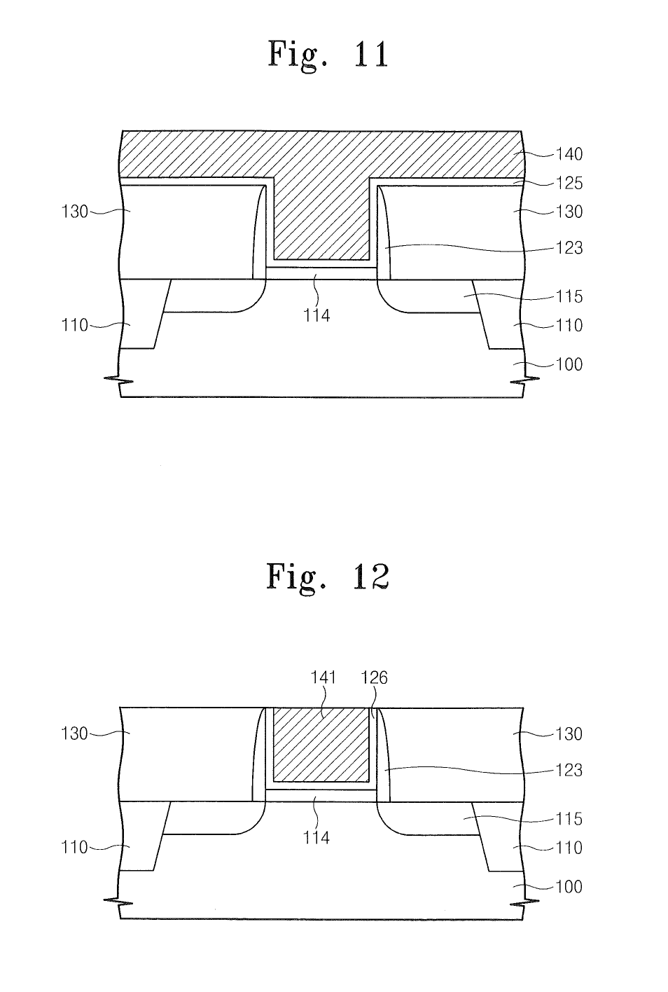

Referring to FIG. 11, a first interlayer dielectric 130 may be formed. After forming the first interlayer dielectric 130, a recess region (124 in FIG. 3) may be formed by removing the dummy gate pattern 122 and the dummy dielectric pattern 121. The dummy gate pattern 122 and the dummy dielectric pattern 121 may be removed by a selective etching process. The recess region may expose the substrate 100. Impurities to adjust a threshold voltage may be doped in a channel region under the recess region. Doping the impurity may be performed using the first interlayer dielectric 130 as a mask. When performing doping the impurity, a portion of the dummy dielectric pattern 121 may remain and be used as a buffer layer for an ion implantation.

A gate dielectric layer 114 may be formed under the recess region. The gate dielectric layer 114 may comprise a high-k film having a high dielectric constant. The gate dielectric layer 114 may comprise at least one selected from the group consisting of a metal oxide, for example, hafnium oxide, and metal-semiconductor-oxide compound film, for example, hafnium-silicon-oxygen-nitrogen compound. The gate dielectric layer 114 may be formed by CVD or ALD. A provisional liner 125 may be formed on the first interlayer dielectric layer 130 and the gate dielectric layer 114. The provisional liner 125 may comprise an oxide, nitride, or oxynitride layer. The provisional liner 125 may be formed by CVD. A first conductive layer 140 may be formed on the provisional liner 125. The first conductive layer 140 may comprise aluminum (Al). The first conductive layer 145 may be formed by PVD.

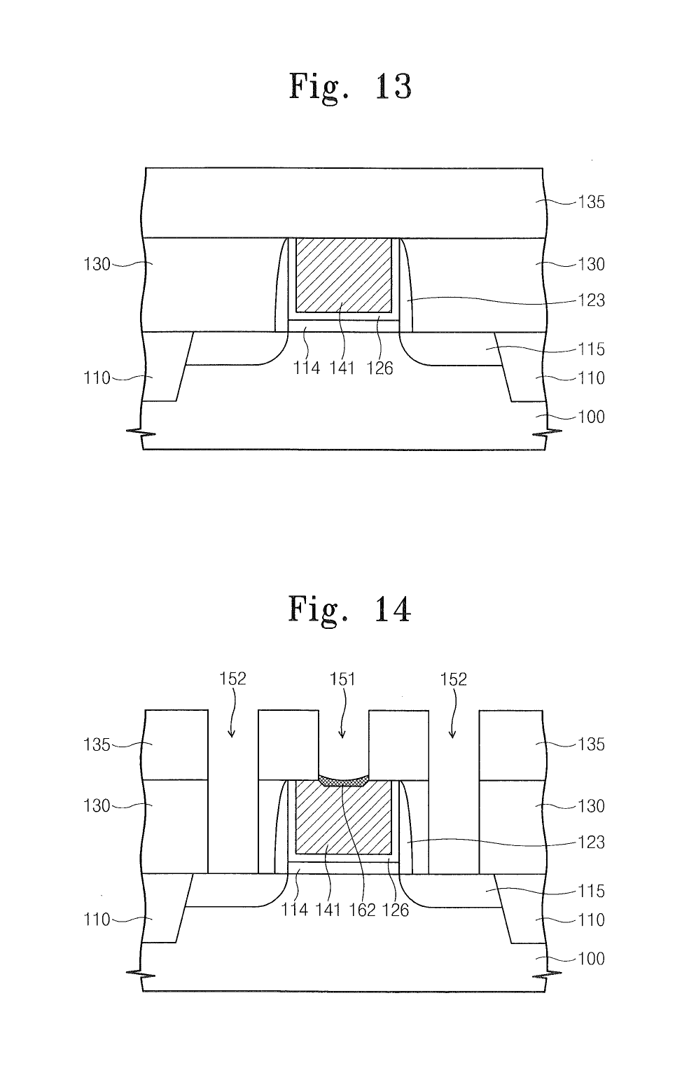

Referring FIG. 12, the first conductive layer 140 and the provisional liner 125 may be planarized until the first interlayer dielectric 130 is exposed. The planarization process may be an etch-back or CMP. By the planarization process, a metal gate electrode 141 and a liner 126 may be formed. The metal gate electrode 141 may be formed by methods other than the damascene process as described above. For example, the metal gate electrode 141 may be formed, without dummy patterns, by forming a high-k film and a conductive layer on the substrate 100 and patterning them. The liner 126 may further prevent the diffusion of materials from the metal gate electrode 141. Referring to FIG. 13, a second interlayer dielectric 135 may be formed on the metal gate electrode 141 and the first interlayer dielectric 130. The second interlayer dielectric 135 may be an oxide, nitride, or oxynitride layer. The second interlayer dielectric 135 may be formed by CVD.

Referring to FIG. 14, a gate contact hole 151 and a drain/source contact hole 152 may be formed. The gate contact hole 151 may be formed, penetrating the second interlayer dielectric 135, to expose the upper surface of the metal gate electrode 141. The source/drain contact hole 152 may be formed, penetrating the first interlayer dielectric 130 and the second interlayer dielectric 135, to expose the source/drain region 115. The gate contact hole 151 may be formed simultaneously with the source/drain contact hole 152. The forming process of the gate contact hole 151 may further comprise etching a portion of an upper surface of the metal gate electrode 141.

A gate protection pattern 162 may be selectively formed on the upper surface of the metal gate electrode 141, which is exposed by the gate contact hole 151. The upper surface of the gate protection pattern 162 may be higher than the bottom surface of the interlayer dielectric 130. An edge of the gate protection pattern 162 may be thicker than a center of the gate protection pattern. The gate protection pattern 162 may comprise cobalt alloys or nickel alloys including tungsten (W) and/or phosphor (P). The gate protection pattern 162 may further comprise boron (B). The gate protection pattern 162 may be selectively formed on the exposed metal gate electrode 141 in the gate contact hole 151 and may not be formed on the exposed source/drain 115 in the source/drain contact hole 152. The gate protection pattern 162 may be selectively formed on the bottom portion of the gate contact hole 151 and may not be formed on an inner sidewall of the gate contact hole 151. As a result, reliability degradation of interconnections due to agglomeration, which may occur when forming the gate protection pattern 162 on the inner sidewall of the gate contact hole 151, may be prevented.

The gate protection pattern 162 may be formed by electroless plating. The electroless plating may use nickel sulfate (NiSO₄) and/or cobalt sulfate (CoSO₄) as a precursor. The electroless plating may use DMBA (Dimethyl Amino Borane) and/or MB (Morpholine Borane) as a reducing agent. The electroless plating may additionally use a catalyst. The electroless plating may be performed by oxidations of reducing agents and reduction of metal ions. In other words, oxidation of reducing agents supplies electrons, which combines with the metal ion and thereby forms a metal pattern. The electroless plating may be performed in a liquid of a temperature between 50 and 90° C. The electroless plating may be performed at the condition of pH 8˜12. The gate protection pattern 162 may be selectively formed on a exposed metallic material, namely the metal gate electrode 141 by the electroless plating. The gate protection pattern 162 may be formed by selective CVD. The selective CVD process may be performed using the difference of the thermodynamic stability between the exposed metal gate electrode 141 and other parts.

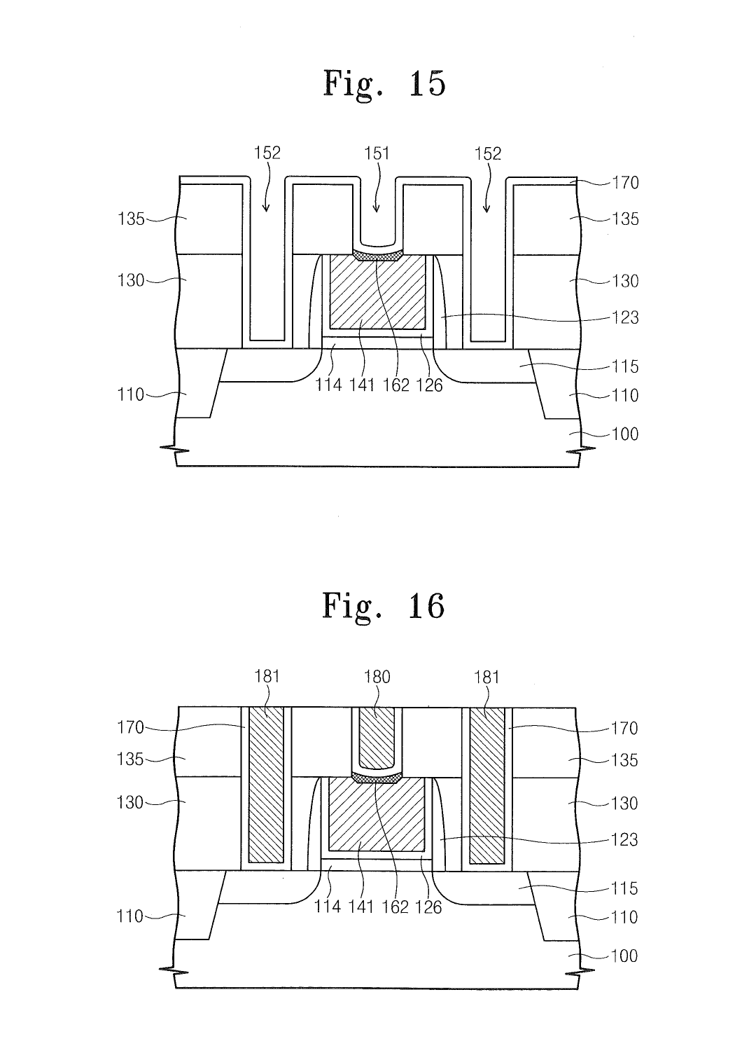

Referring to FIG. 15, a barrier layer 170 may be formed in the gate contact hole 151 and the source/drain contact hole 152. The barrier layer 170 may be a titanium nitride layer, tungsten nitride layer or tungsten carbonitride layer. The barrier layer 170 may be formed by CVD or ALD, which is performed at equal to or less than 450° C. The barrier layer 170 may be formed by using WF₆ or TiCl₄ as a source. Particularly, in the case that the metal gate electrode 141 comprises aluminum, a high resistivity material, such as TiAl₃ may be formed on the metal gate electrode 141 or corrosion of the metal gate electrode 141 may occur. When forming the barrier layer 170, the gate protection pattern 162 may prevent the formation of a high resistivity material and damages of the metal gate electrode 141.

Referring to FIG. 16, a gate contact plug 180 may be formed in the gate contact hole 151 and a source/drain contact plug 181 may be formed in the source/drain contact hole 152. The gate contact plug 180 and the source/drain contact plug 181 may be formed by forming a second conductive layer (not shown) on the barrier layer 170 and then performing a planarization process. After the planarization process, the barrier layer 170 may be separated to be positioned on inner areas of the respective contact holes. The gate contact plug 180 and the source/drain contact plug 181 may comprise tungsten (W). The gate contact plug 180 and the source/drain contact plug 181 may be formed by CVD or PVD. The gate contact plug 180 and the source/drain contact plug 181 may be formed by using WF₆ as a source. When forming the barrier layer 170 or in the case that the barrier layer 170 is thin, the gate protection pattern 162 may prevent the metal gate electrode 141 from being damaged by the WF₆ during forming the contact plug.

Although some embodiments of the present inventive concept are illustrated referring to the attached drawings, it is readily apparent to those skilled in the art that the present inventive concept can have various different combinations and/or modifications without modifying its technical concept or essential features. Therefore, the foregoing disclosure is illustrative and not intended to limit the present inventive concept in any way.

By forming a gate protection pattern between a metal gate electrode and a barrier layer, the damage problems of the metal gate electrode, which occurs during forming a barrier layer, can be solved. As a result, a semiconductor device having an improved electric characteristics and reliability can be achieved.

1. A method of forming a field effect transistor, comprising:
forming a metal alloy gate electrode containing about 0.5 to about 1.0 atomic percent silicon, on a substrate; and
electroless plating an electrically conductive gate protection layer on at least a portion of an upper surface of the metal alloy gate electrode.

2. The method of claim 1, further comprising forming a gate dielectric layer on the substrate, said gate dielectric layer having a dielectric constant greater than a dielectric constant of silicon dioxide; and wherein said forming a metal alloy gate electrode comprises forming a metal alloy gate electrode directly on an upper surface of the gate dielectric layer.

3. The method of claim 2, wherein the electrically conductive gate protection layer comprises a metal alloy selected from a group consisting of a cobalt alloy and a nickel alloy.

4. The method of claim 3, wherein the metal alloy comprises at least one of tungsten and phosphorous.

5. The method of claim 2, further comprising depositing a barrier layer on the electrically conductive gate protection layer, said barrier layer comprising at least one of a titanium nitride layer, a tungsten nitride layer and a tungsten carbonitride layer.

6. The method of claim 2, wherein metal alloy gate electrode is an aluminum alloy gate electrode.

7. The method of claim 1, wherein said forming a metal alloy gate electrode is preceded by:
forming a dummy dielectric pattern on the substrate;
forming a dummy gate pattern on an upper surface of the dummy dielectric pattern;
forming gate spacers on sidewalls of the dummy gate pattern; and
removing the dummy gate pattern and dummy dielectric pattern in sequence to expose inner sidewalls of the gate spacers.

8. The method of claim 7, wherein said removing is followed by forming a gate dielectric layer on a portion of the substrate extending between the inner sidewalls of the gate spacers.

9.-10. (canceled)

11. The method of claim 1, wherein said electroless plating comprises using dimethyl amino borane and/or morpholine borane as a reducing agent.

12. The method of claim 11, wherein said electroless plating comprises using nickel sulfate and/or cobalt sulfate as a precursor.

13. A method of forming a semiconductor device, comprising:
forming a gate dielectric pattern and a metal gate electrode on a substrate;
forming a interlayer dielectric including a gate contact hole on the metal gate electrode;
selectively forming a gate protection pattern on the metal gate electrode exposed by the gate contact hole, and
forming a barrier layer and a gate contact plug on the gate protection pattern.

14. The method of claim 13, wherein the metal gate electrode comprises aluminum (Al).

15. The method of claim 14, wherein the metal gate electrode further comprises 0.5˜1% of silicon (Si).

16. The method of claim 13, wherein forming the gate protection pattern comprises selectively forming the gate protection pattern on a metallic material.

17. The method of claim 16, wherein forming the gate protection pattern is performed by an electroless plating or selective CVD.

18. The method of claim 17, wherein nickel sulfate (NiSO₄) and/or cobalt sulfate (CoSO₄) is used as a precursor.

19. The method of claim 18, wherein the electroless plating uses DMBA (Dimethyl Amino Borane) and/or MB (Morpholine Borane) as a reducing agent.

20. The method of claim 13, wherein the gate protection pattern comprises cobalt alloys or nickel alloys including tungsten (W) or phosphor (P).

21. (canceled)

22. The method of claim 13, wherein forming the gate contact hole further comprises etching a portion of an upper surface of the metal gate electrode.

23. (canceled)

24. The method of claim 13, further comprising forming a source/drain contact hole exposing a portion of source/drain region on the substrate in the interlayer dielectric, wherein the gate protection pattern is selectively formed within the gate contact hole among the gate contact hole and the source/drain contact hole.

25.-32. (canceled)
